(19) United States
(12) Patent Application Publication
(10) Pub. No.: US 2024/0049559 A1
(43) Pub. Date: Feb. 8, 2024

(54) DISPLAY DEVICE AND METHOD OF MANUFACTURING THE SAME

(71) Applicant: Samsung Display Co., LTD., Yongin-si (KR)

(72) Inventors: Dong Min LEE, Yongin-si (KR); Dong Min LEE, Yongin-si (KR); Dong Gyu JIN, Yongin-si (KR)

(21) Appl. No.: 18/125,283

(22) Filed: Mar. 23, 2023

(30) Foreign Application Priority Data
Aug. 4, 2022 (KR) 10-2022-0097423

(51) Int. Cl. H10K 59/80; H10K 59/124; H10K 59/12

(52) U.S. Cl. CPC H10K 59/80; H10K 59/124; H10K 59/1201

(57) ABSTRACT

A display device and a method of manufacturing the same are provided. The display device includes: a base substrate, a barrier layer disposed on the base substrate, a first metal layer disposed on the barrier layer, a second metal layer disposed on the base substrate and spaced apart from the first metal layer, a buffer layer disposed on the first metal layer and the second metal layer, and a plurality of thin film transistors disposed on the buffer layer, where an angle between a side surface of the barrier layer and a bottom surface of the barrier layer is equal to or more than 90 degrees and less than or equal to 150 degrees.

This application claims priority to Korean Patent Application No. 10-2022-0097423 filed on Aug. 4, 2022, and all the benefits accruing therefrom under 35 U.S.C. 119, the contents of which in its entirety are herein incorporated by reference.

### BACKGROUND

### 1. Technical Field

The present disclosure relates to a display device and a method of manufacturing the same.

### 2. Description of the Related Art

With the advance of information-oriented society, more and more demands are placed on display devices for displaying images in various ways. For example, a display device is employed in various electronic devices such as smartphones, digital cameras, laptop computers, navigation devices, and smart televisions.

The display device may be a flat panel display device such as a liquid crystal display device, a field emission display device, and an organic light emitting display device. Examples of the light emitting display device include an organic light emitting display device composed of organic light emitting elements, an inorganic light emitting display device composed of inorganic light emitting elements such as inorganic semiconductors, and a micro light emitting display device composed of micro light emitting elements.

The display device includes alight emitting diode and a plurality of thin film transistors connected to the light emitting diode. The plurality of thin film transistors may include thin film transistors including polycrystalline silicon.

### SUMMARY

Aspects of the present disclosure provide a display device capable of preventing damage to a substrate due to heat during manufacturing of polycrystalline silicon and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes: a base substrate, a barrier layer disposed on the base substrate, a first metal layer disposed on the barrier layer, a second metal layer disposed on the base substrate and spaced apart from the first metal layer, a buffer layer disposed on the first metal layer and the second metal layer, and a plurality of thin film transistors disposed on the buffer layer, where an angle between a side surface of the barrier layer and a bottom surface of the barrier layer is equal to or more than 90 degrees and less than or equal to 150 degrees.

In an embodiment, the barrier layer may have a reversed-tapered shape.

In an embodiment, the angle between the side surface of the barrier layer and the bottom surface of the barrier layer may be greater than 90 degrees and equal to or less than 150 degrees.

In an embodiment, a width of the bottom surface of the barrier layer may be smaller than a width of a top surface of the barrier layer.

In an embodiment, the first metal layer and the second metal layer may contain the same material.

In an embodiment, the first metal layer may be in contact with a top surface of the barrier layer and the second metal layer is in contact with a top surface of the base substrate.

In an embodiment, the second metal layer may be spaced apart from the side surface of the barrier layer.

In an embodiment, a planar area of the first metal layer may be the same as a planar area of the barrier layer.

In an embodiment, each of thicknesses of the first metal layer and a second metal layer may be smaller than a thickness of the barrier layer.

In an embodiment, a height of a top surface of the second metal layer may be smaller than a height of a bottom surface of the first metal layer, and the heights may be measured in a direction perpendicular to a top surface of the base substrate.

In an embodiment, the first metal layer and the second metal layer may not overlap each other in a plan view.

According to an aspect of the present disclosure, a display device includes a first base substrate, a first barrier layer disposed on the first base substrate, a first metal layer disposed on the first barrier layer, a second metal layer disposed on the first base substrate and spaced apart from the first metal layer, a buffer layer disposed on the first metal layer and the second metal layer, and a plurality of thin film transistors disposed on the buffer layer, where an angle between a side surface of the first barrier layer and a top surface of the first base substrate is about 90 degrees.

In an embodiment, the second metal layer may be in contact with the side surface of the first barrier layer.

In an embodiment, the side surface of the first barrier layer and a side surface of the first metal layer may be aligned and coincide with each other.

In an embodiment, the plurality of thin film transistors may include an active layer, a gate electrode, a source electrode, and a drain electrode, and wherein the active layer overlaps the first metal layer in a plan view.

In an embodiment, the display device may further include a second base substrate disposed under the first base substrate, and a second barrier layer disposed between the first base substrate and the second base substrate.

According to an aspect of the present disclosure, a method for fabrication of a display device, includes: forming a barrier layer on a base substrate, where an angle between a side surface of the barrier layer and a bottom surface of the barrier layer is equal to or more than 90 degrees and less than or equal to 150 degrees; forming a first metal layer and a second metal layer spaced apart from the first metal layer by stacking a metal material layer on the base substrate; forming a buffer layer on the first metal layer and the second metal layer; forming an amorphous silicon layer on the buffer layer, and irradiating a laser to the amorphous silicon layer to form a polycrystalline silicon layer; and forming an active layer by patterning the polycrystalline layer, and forming a gate electrode, a source electrode, and a drain electrode to form a thin film transistor.

In an embodiment, the barrier layer may be formed by forming a barrier material layer on the base substrate and inducing over-etching using a photoresist pattern as a mask.

In an embodiment, the first metal layer and the second metal layer may be formed by being separated by the barrier layer when stacking the metal material layers.

In an embodiment, the laser may be irradiated using a solid laser annealing (“SLA”) method.

According to the display device and the method for manufacturing the same according to embodiments, a first metal layer and a second metal layer may be formed without using a mask, by forming the angle of the side surface of a second barrier layer to be 90 degrees or more. In addition, by forming the second metal layer in a region other than the region where the first metal layer is disposed, transfer of heat from the laser to the substrate may be blocked when the active layer of the thin film transistor is crystallized. Accordingly, outgassing and the peeling of the substrate may be effectively improved.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to one embodiment;

FIG. 2 is a plan view of one example of a display panel according to one embodiment;

FIG. 3 is a circuit diagram of one example of a sub-pixel of FIG. 2;

FIG. 4 is a cross-sectional view illustrating a display device according to one embodiment;

FIG. 5 is an enlarged view of one example of region A of FIG. 4;

FIG. 6 is another enlarged view of another example of region A of FIG. 4;

FIG. 7 is a graph illustrating a temperature of a second base substrate during SLA crystallization according to a comparative example;

FIG. 8 is a graph illustrating a temperature of a second base substrate during SLA crystallization according to a one embodiment; and

FIGS. 9 to 16 are views for each step illustrating a manufacturing method of a display device according to one embodiment.

### DETAILED DESCRIPTION

The present disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, embodiments will be described in detail with reference to the accompanying drawings.

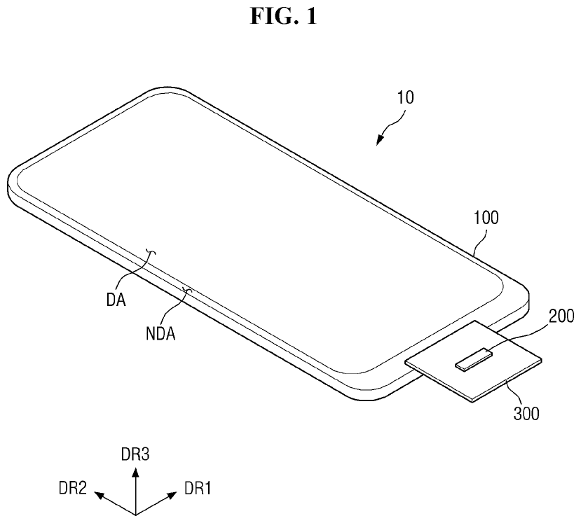

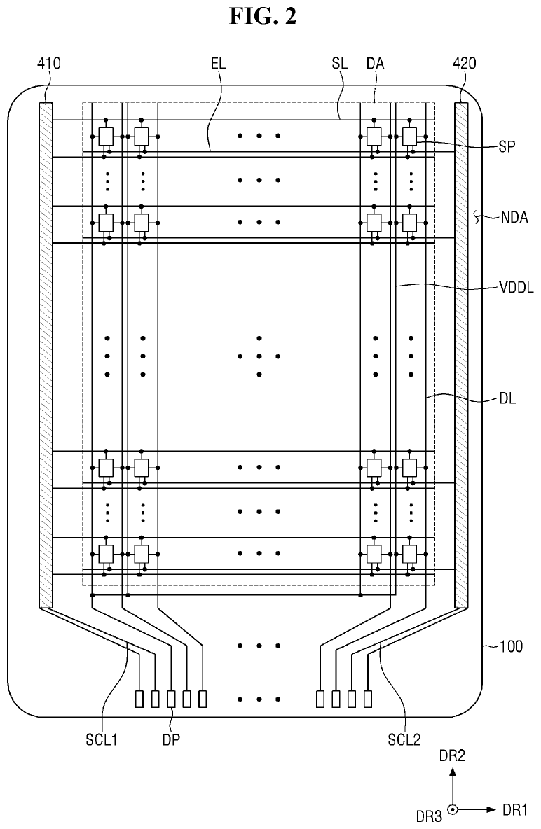

FIG. 1 is a perspective view of a display device according to one embodiment. FIG. 2 is a plan view of one example of a display panel according to one embodiment. As used herein, the “plan view” is a view in a thickness direction (i.e., third direction DR3) of the display device 10.

The terms “above,” “top,” and “top surface” as used herein refer to an upward direction (i.e., one side of a third direction DR3) with respect to a display panel 100. The terms “below,” “bottom,” and “bottom surface” as used herein refer to a downward direction (i.e., the other side of the third direction DR3) with respect to a display panel 100.

A display device 10 is a device for displaying a moving image or a still image. The display device 10 may be used as a display screen of various devices, such as a television, a laptop computer, a monitor, a billboard and an Internet-of-Things (“IOT”) device, as well as portable electronic devices such as a mobile phone, a smartphone, a tablet personal computer (“PC”), a smart watch, a watch phone, a mobile communication terminal, an electronic notebook, an electronic book, a portable multimedia player (“PMP”), a navigation device and an ultra-mobile PC (“UMPC”). The display device 10 may be any one of an organic light emitting display device, a liquid crystal display device, a plasma display device, afield emission display device, an electrophoretic display device, an electrowetting display device, a quantum dot light emitting display device, a micro LED display device, and the like. In the following, an organic light emitting display device will be described as an example of the display device 10, but the display device 10 is not limited thereto.

Referring to FIGS. 1 and 2, the display device 10 according to one embodiment includes the display panel 100, a display driver 200, and a circuit board 300.

The display panel 100 may, in a plan view, be formed in a rectangular shape having short sides in a first direction DR1 and long sides in a second direction DR2 crossing the first direction DR1. A corner where the short side in the first direction DR1 and the long side in the second direction DR2 meet may be right-angled or rounded to have a predetermined curvature. The planar shape of the display panel 100 is not limited to the rectangular shape, and may be formed in another polygonal shape, a circular shape or an elliptical shape. The display panel 100 may be formed to be flat, but is not limited thereto, and the display panel 100 may include a curved portion formed at left and right ends and having a predetermined curvature or a varying curvature. In addition, the display panel 100 may be formed flexibly so that it can be curved, bent, folded, or rolled.

The display panel 100 may include a display area DA where sub-pixels SP are formed to display an image and a non-display area NDA which is a peripheral area of the display area DA. When the display panel 100 includes a curved portion, the display area DA may be disposed on the curved portion. In this case, the image of the display panel 100 may be seen even on the curved portion.

In addition to the sub-pixels PX, scan lines SL connected to the sub-pixels PX, emission lines EL, data lines DL, and first driving voltage lines VDDL may be arranged in the display area DA. The scan lines SL and the emission lines EL may be formed in parallel in a first direction DR1, and the data lines DL may be formed in parallel in a second direction DR2 intersecting the first direction DR1. The first driving voltage lines VDDL may be formed in parallel along the second direction DR2 in the display area DA. The first driving voltage lines VDDL formed in parallel along the second direction DR2 in the display area DA may be connected to each other in the non-display area NDA.

Each of the sub-pixels SP may be connected to at least one of the scan lines SL, one of the data lines DL, at least one of the emission lines EL, and one of the first driving voltage lines VDDL. Although it is illustrated in FIG. 2 that each of the sub-pixels SP is connected to two scan lines SL, one data line DL, one emission line EL, and the first driving voltage line VDDL for simplicity of descriptions, the present disclosure is not limited thereto. For example, each of the sub-pixels SP may be connected to three scan lines SL rather than two scan lines SL.

Each of the sub-pixels SP may include a driving transistor, at least one switching transistor, a light emitting element, and a capacitor. The driving transistor may emit light by supplying a driving current to the light emitting element according to the data voltage applied to the gate electrode. The driving transistor and at least one transistor may be a thin film transistor TFT. The light emitting element may emit light according to the driving current of the driving transistor. The light emitting element may be an organic light emitting diode including an anode electrode, an organic light emitting layer and a cathode electrode. The capacitor may serve to keep constant the data voltage applied to the gate electrode of the driving transistor.

The non-display area NDA may be defined as an area from the boundary of the display area DA to the edge of the display panel 100. In the non-display area NDA, a scan driver 410 for applying scan signals to the scan lines SL and the pads DP connected to the data lines DL may be disposed. Since the circuit board 300 is attached to the pads DP, the pads DP may be disposed on one edge of the display panel 100, for example, a lower edge of the display panel 100.

The scan driver 410 may be connected to the display driver 200 through a plurality of first scan control lines SCL1. The scan driver 410 may receive a scan control signal from the pads DP through the plurality of first scan control lines SCL1. The scan driver 410 may generate scan signals in response to the scan control signal and sequentially output the scan signals to the scan lines SL. Sub-pixels SP to which data voltages are to be supplied are selected by the scan signals of the scan driver 410, and data voltages are supplied to the selected sub-pixels SP.

An emission control driver 420 may be connected to the display driver 200 through a plurality of second scan control lines SCL2. The emission control driver 420 may receive an emission control signal from the pads DP through the plurality of second scan control lines SCL2. The emission control driver 420 may generated emission control signals in response to the emission control signal and sequentially output the emission control signals to the emission lines EL.

Although FIG. 2 illustrates that the scan driver 410 is disposed outside the one side of the display area DA and the emission control driver 420 is disposed outside the other side of the display area DA, the present disclosure is not limited thereto. Both the scan driver 410 and the emission control driver 420 may be disposed outside only one side of the display area DA, or may be disposed outside both sides of the display area DA.

The display driver 200 receives digital video data and timing signals from the outside. The display driver 200 may convert the digital video data into analog positive/negative data voltages and supply them to data lines DL. The display driver 200 may generate and supply a scan control signal for controlling an operation timing of the scan driver 410 through the first scan control lines SCL1. The display driver 200 may generate and supply an emission control signal for controlling an operation timing of the emission control driver 420 through the second scan control lines SCL2. In addition, the display driver 200 may supply a first driving voltage to a first driving voltage line VDDL.

The display driver 200 may be formed as an integrated circuit (“IC”) and attached on the circuit board 300 in a chip on film (“COF”) structure. Alternatively, the display driver 200 may be attached to the display panel 100 in a chip on glass (“COG”) method, a chip on plastic (“COP”) method or an ultrasonic bonding method.

The circuit board 300 may be attached to the pads DP using an anisotropic conductive film (“ACF”). Accordingly, lead lines of the circuit board 300 may be electrically connected to the pads DP. The circuit board 300 may be a flexible film such as a flexible printed circuit board, a printed circuit board, or a chip on film.

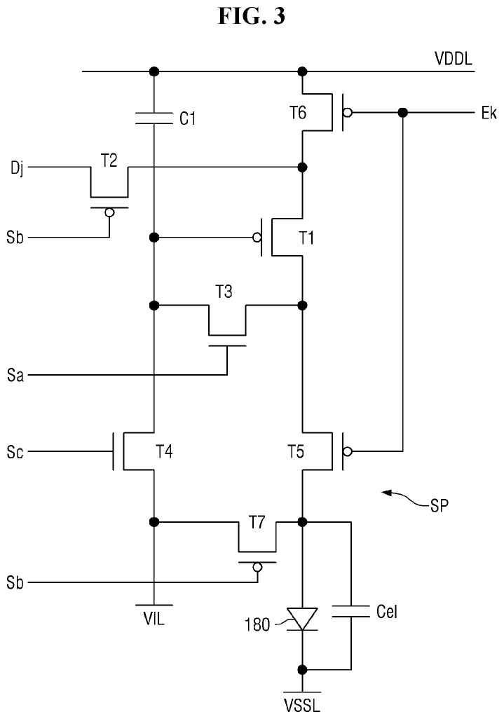

FIG. 3 is a circuit diagram of one example of a sub-pixel of FIG. 2.

In FIG. 3, a circuit of one sub-pixel SP of the display device may include an organic light emitting diode 180, a plurality of transistors T1 to T7, and a capacitor C1. A data line Dj, a first scan line Sa, a second scan line Sb, a third scan line Sc, an emission line Ek, the first driving voltage line VDDL, a second driving voltage line VSSL, and an initialization voltage line VIL may be connected to a circuit of one sub-pixel.

The organic light emitting diode 180 may include an anode electrode and a cathode electrode. The capacitor C1 may include a first electrode and a second electrode.

The plurality of transistors may include first to seventh transistors T1 to T7. Each of the transistors T1 to T7 may include a gate electrode, a first electrode and a second electrode. One of the first and second electrodes of each of the transistors T1 to T7 may be a source electrode and the other electrode may be a drain electrode.

Each of the transistors T1 to T7 may be a thin film transistor. The transistors T1 to T7 may each be one of a PMOS transistor and a NMOS transistor. In one embodiment, the first transistor T1 as a driving transistor, the second transistor T2 as a data transfer transistor, the fifth transistor T5 as a first light emitting control transistor, the sixth transistor T6 as a second light emitting control transistor, and the seventh transistor T7 as a second initialization transistor may each be a PMOS transistor. On the other hand, the third transistor T3 which is a compensation transistor and the fourth transistor T4 which is a first initialization transistor are NMOS transistors. The PMOS transistor and the NMOS transistor differ in characteristics, and the third transistor T3 and the fourth transistor T4 may each be formed as an NMOS transistor having relatively superior turn-off characteristics, which may reduce leakage of a driving current during the light emission period of the organic light emitting diode OLED.

Hereinafter, each component will be described in detail.

The gate electrode of the first transistor T1 is connected to the first electrode of the capacitor C1. The first electrode of the first transistor T1 is connected to the first driving voltage line VDDL terminal via the sixth transistor T6. The second electrode of the first transistor T1 is connected to the anode electrode of the organic light emitting diode 180 via the fifth transistor T5. The first transistor T1 supplies the driving current to the organic light emitting diode 180 based on a data signal DATA received according to a switching operation of the second transistor T2.

The gate electrode of the second transistor T2 is connected to the second scan line Sb terminal. The first electrode of the second transistor T2 is connected to the data line Dj terminal. The second electrode of the second transistor T2 is connected to the first electrode of the first transistor T1 and also connected to the first driving voltage line VDDL terminal via the sixth transistor T6. The second transistor T2 is turned on according to a signal applied to the second scan line Sb and performs a switching operation of transmitting the data signal applied through the data line Dj to the first electrode of the first transistor T1.

The gate electrode of the third transistor T3 is connected to the first scan line Sa terminal. The first electrode of the third transistor T3 is connected to the second electrode of the first transistor T1 and also connected to the anode electrode of the organic light emitting diode 180 via the fifth transistor T5. The second electrode of the third transistor T3 is connected simultaneously to the first electrode of the capacitor C1, the first electrode of the fourth transistor T4, and the gate electrode of the first transistor T1. The third transistor T3 is turned on, according to the first scan line Sa, to connect the gate electrode and the second electrode of the first transistor T1, whereby the first transistor T1 forms a diode connection. Accordingly, a voltage difference corresponding to a threshold voltage of the first transistor T1 is generated between the gate electrode and the first electrode of the first transistor T1, and a data signal in which the threshold voltage is compensated is supplied to the gate electrode of the first transistor T1, thereby compensating for a threshold voltage deviation of the first transistor T1.

The gate electrode of the fourth transistor T4 is connected to the third scan line Sc terminal. The second electrode of the fourth transistor T4 is connected to the initialization voltage line VIL terminal. The first electrode of the fourth transistor T4 is connected simultaneously to the first electrode of the capacitor C1, the second electrode of the third transistor T3, and the gate electrode of the first transistor T1. The fourth transistor T4 is turned on according to the third scan line Sc to transfer an initialization voltage signal of the initialization voltage line VIL to the gate electrode of the first transistor T1 to carry out an operation of initializing the voltage of the gate electrode of the first transistor T1.

The gate electrode of the fifth transistor T5 is connected to the emission line Ek terminal. The first electrode of the fifth transistor T5 is connected to the second electrode of the first transistor T1 and the first electrode of the third transistor T3. The second electrode of the fifth transistor T5 is connected to the anode electrode of the organic light emitting diode 180.

The gate electrode of the sixth transistor T6 is connected to the emission line Ek terminal. The first electrode of the sixth transistor T6 is connected to the first driving voltage line VDDL. The second electrode of the sixth transistor T6 is connected to the first electrode of the first transistor T1 and the second electrode of the of the second transistor T2.

The fifth transistor T5 and the sixth transistor T6 are simultaneously turned on in response to the emission control signal so that the driving current flows through the organic light emitting diode 180.

The gate electrode of the seventh transistor T7 is connected to the second scan line Sb terminal. The first electrode of the seventh transistor T7 is connected to the anode electrode of the organic light emitting diode 180. The second electrode of the seventh transistor T7 is connected to the initialization voltage line VIL. The seventh transistor T7 is turned on according to the emission control signal of the emission line Ek to initialize the anode electrode of the organic light emitting diode 180.

In the present embodiment, the gate electrode of the seventh transistor T7 receives the second scan line Sb. However, in another embodiment, a pixel circuit may be configured such that the gate electrode of the seventh transistor T7 receives the emission control signal of the emission line Ek.

The second electrode of the capacitor C1 is connected to the first driving voltage line VDDL terminal. The first electrode of the capacitor C1 is connected simultaneously to the gate electrode of the first transistor T1, the second electrode of the third transistor T3, and the first electrode of the fourth transistor T4. The cathode electrode of the organic light emitting diode 180 is connected to the second driving voltage line VSSL terminal. The organic light emitting diode 180 receives the driving current from the first transistor T1 and emits light to display an image.

Each of the first to seventh transistors T1, T2, T3, T4, T5, T6, and T7 may include a semiconductor layer. A portion of the first to seventh transistors T1, T2, T3, T4, T5, T6, and T7 may include a semiconductor layer made of polycrystalline silicon, and the remaining portion of the first to seventh transistors T1, T2, T3, T4, T5, T6, and T7 may include a semiconductor layer made of an oxide. For example, the semiconductor layers of the first to seventh transistors T1, T2, T3, T4, T5, T6, and T7 may be made of polycrystalline silicon, or the semiconductor layers of the first transistor T1 and the fifth transistor T5 to the seventh transistor T7 may be made of polycrystalline silicon, and the semiconductor layers of the third transistor T3 and the fourth transistor T4 may be made of an oxide. For example, the semiconductor layer of the driving transistor may include polycrystalline silicon, and the semiconductor layer of the switching transistor may include oxide.

The semiconductor layer of the switching transistor may include a first channel region overlapping the gate electrode of the switching transistor, a first drain region positioned on one side of the first channel region, and a first source region positioned on the other side of the first channel region. The semiconductor layer of the driving transistor may include a second channel region overlapping the gate electrode of the driving transistor, a second drain region positioned on one side of the second channel region, and a second source region positioned on the other side of the second channel region.

The above-described display device 10 may include a flexible material such as plastic to realize the display device 10 that can be bent. For one example, the substrate may include polyimide. Polyimide is a flexible insulating substrate and can be used as a substrate for various flexible display devices. However, in a substrate including polyimide, a charging phenomenon may occur in which electrons are collected on a surface, and electrical characteristics of a thin film transistor adjacent to the substrate may be deteriorated due to this electron charging.

Hereinafter, a display device capable of preventing deterioration of characteristics of a thin film transistor by improving electron charging of a substrate will be described.

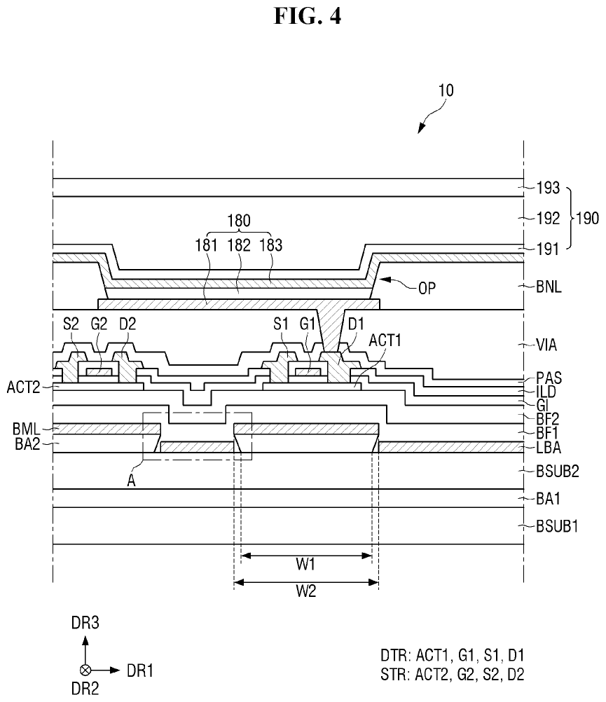

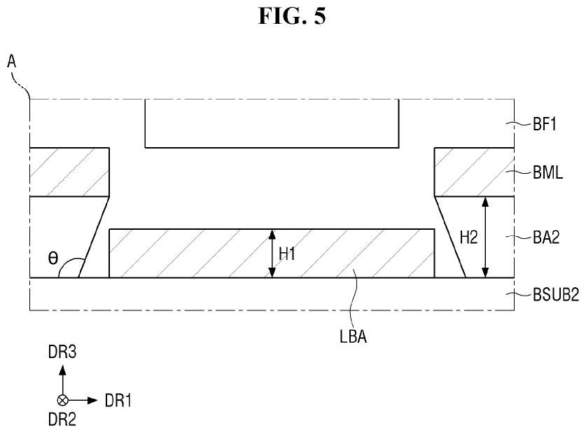

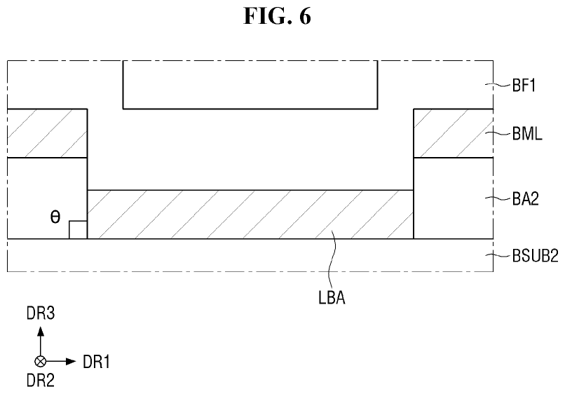

FIG. 4 is a cross-sectional view illustrating a display device according to one embodiment. FIG. 5 is an enlarged view of one example of region A of FIG. 4. FIG. 6 is another enlarged view of another example of region A of FIG. 4.

Referring to FIGS. 4 to 6, the display device 10 according to one embodiment may include base substrates BSUB1 and BSUB2, barrier layers BA1 and BA2, a first metal layer BML, a second metal layer LBA, buffer layers BF1 and BF2, a switching transistor ST disposed on the buffer layers BF1 and BF2, a driving transistor DT, an organic light emitting diode 180 and an encapsulation layer 190.

Specifically, the first base substrate BSUB1 may support the respective layers disposed thereon. A transparent substrate as the first base substrate BSUB1 may be used when the display device is a bottom emission type or a double-sided emission type. When the display device is a top emission type, in addition to a transparent substrate, a translucent or opaque substrate may be applied to first base substrate BSUB1. The first base substrate BSUB1 may include a flexible material such as plastic, for example, polyimide.

The first barrier layer BA1 may be disposed on the first base substrate BSUB1. The first barrier layer BA1 may prevent diffusion of impurity ions, prevent penetration of moisture or external air, and may perform a surface planarization function. The first barrier layer BA1 may include silicon nitride, silicon oxide, or silicon nitride oxide.

The second base substrate BSUB2 may be disposed on the first barrier layer BA1. The second base substrate BSUB2 may include a flexible material such as plastic, for example, polyimide. The second base substrate BSUB2 may include the same material as the first base substrate BSUB1.

The second barrier layer BA2 may be disposed on the second base substrate BSUB2. The second barrier layer BA2 may prevent diffusion of impurity ions and may prevent penetration of moisture or external air. The second barrier layer BA2 may include silicon nitride, silicon oxide, or silicon nitride oxide.

According to one embodiment, the second barrier layer BA2 may be partially disposed on the second base substrate BSUB2. For example, the first barrier layer BA1 may be disposed on the entire surface of the first base substrate BSUB1, but the second barrier layer BA2 may be partially disposed and may have a pattern shape. The second barrier laver BA2 may be disposed under the first metal layer BML, which will be described later, and may overlap the first metal layer BML in a plan view. In an embodiment, the first metal layer BML may cover the entire second barrier layer BA2.

According to one embodiment, the second barrier layer BA2 may be formed by simultaneously forming the first metal layer BML and the second metal layer LBA, which will be described later, through the same process. Reference will be made to FIGS. 5 and 6 for a description thereof.

Referring to FIG. 5 in conjunction with FIG. 4, the second barrier layer BA2 may have a reversed-tapered shape. That is, the side surface of the second barrier layer BA2 may have a reversed-tapered shape. The side surface of the second barrier layer BA2 may form an obtuse angle with the top surface of the second base substrate BSUB2 (i.e., the bottom surface of the second barrier layer BA2). An angle θ between the side surface of the second barrier layer BA2 and the second base substrate BSUB2 (i.e., the bottom surface of the second barrier layer BA2) may be greater than 90 degrees. For example, the angle θ between the side surface of the second barrier layer BA2 and the second base substrate BSUB2 (i.e., the bottom surface of the second barrier layer BA2) may be greater than 90 degrees and less than or equal to 150 degrees. However, the present disclosure is not limited thereto.

The width of the lower surface of the second barrier layer BA2 may be smaller than the width of the upper surface of the second barrier layer BA2. Here, a lower surface of the second barrier layer BA2 may be defined as an interface in contact with the second base substrate BSUB2, and an upper surface of the second barrier layer BA2 may be defined as an interface in contact with the first metal layer BML. Specifically, a width W1 of the lower surface of the second barrier layer BA2 in the first direction DR1 may be smaller than a width W2 of the upper surface of the second barrier layer BA2 in the first direction DR1.

As another embodiment, referring to FIG. 6, the side surface of the second barrier layer BA2 may have a vertical shape. That is, the side surface of the second barrier layer BA2 may form a right angle with the top surface of the second base substrate BSUB2. An angle θ between the side surface of the second barrier layer BA2 and the second base substrate BSUB2 may be 90 degrees. However, the present disclosure is not limited thereto. The width of the lower surface of the second barrier layer BA2 may be the same as the width of the upper surface of the second barrier layer BA2. The width W1 of the lower surface of the second barrier layer BA2 in the first direction DR1 may be the same as the width W2 of the upper surface of the second barrier layer BA2 in the first direction DR1.

As illustrated in FIGS. 5 and 6 described above, the angle θ between the side surface of the second barrier layer BA2 and the second base substrate BSUB2 (i.e., the bottom surface of the second barrier layer BA2) may be 90 degrees to 150 degrees. As described later in the structure of the second barrier layer BA2, when the metal layers are stacked, the metal layer may be separated into the first metal layer BML and the second metal layer LBA. Accordingly, there is an advantage in that a mask can be omitted when the first metal layer BML and the second metal layer LBA are manufactured. For more detailed description, reference will be made to a manufacturing method to be described later.

Referring to FIG. 4, the first metal layer BML may be disposed on the second barrier layer BA2. The first metal layer BML is disposed to overlap active layers ACT1 and ACT2 of thin film transistors STR and DTR of the display device 10 in a plan view. The first metal layer BML may include a light-blocking material to prevent light from being incident on the active layers ACT1 and ACT2 of the thin film transistors STR and DTR. The first metal layer BML may include an opaque metal material that blocks light transmission. For example, the first metal layer BML may include molybdenum (Mo), titanium (Ti), tungsten (W), or the like. In an embodiment, the first metal layer BML may include molybdenum (Mo). However, the present disclosure is not limited thereto.

As shown in FIGS. 5 and 6, the first metal layer BML may be directly disposed on the upper surface of the second barrier layer BA2 and may be in contact with the upper surface of the second barrier layer BA2. The first metal layer BML may not protrude to the outside of the side surface of the second barrier layer BA2. In one embodiment, as shown in FIG. 6, the side surface of the first metal layer BML may be aligned with a side surface of the second barrier layer BA2 to coincide with each other in the border between the first metal layer BML and the second barrier layer BA2. Also, the planar area of the first metal layer BML may be substantially the same as the planar area of the second barrier layer BA2. Here, the planar area of the first metal layer BML may be the area of the first metal layer BML in a plan view, and the planar area of the second barrier layer BA2 may be defined as an area occupied by the upper surface of the second barrier layer BA2 in the plan view.

Referring to FIG. 4 again, the second metal layer LBA may be disposed on the second base substrate BSUB2. The second metal layer LBA may be disposed directly on the second base substrate BSUB2 and may be disposed between the second barrier layers BA2. The second metal layer LBA may absorb and block light incident from the outside, and in particular, may block and absorb heat transmitted through a laser beam, which will be described later. The second metal layer LBA may include a material having low heat conductivity, and may include the same material as that of the first metal layer BML. As will be described later, the second metal layer LBA may be formed simultaneously with the same process as that of the first metal layer BML, and may include the same material as that of the first metal layer BML.

In one embodiment, the thickness of the second metal layer LBA may be smaller than the thickness of the second barrier layer BA2. In order to be separated and formed simultaneously with the first metal layer BML through the second barrier layer BA2, the second metal layer LBA may be formed to be smaller than the thickness of the second barrier layer BA2. Similarly, the first metal layer BML may be formed to be smaller than the thickness of the second barrier layer BA2. The second metal layer LBA and the first metal layer BML may have the same thickness. In an embodiment, the thickness of each of the first metal layer BML and the second metal layer LBA may be in a range of 500 Å to 5000 Å, but is not limited thereto.

In addition, a height H1 of the upper surface of the second metal layer LBA may be smaller than a height H2 of the lower surface of the first metal layer BML. Here, the height H1 of the upper surface of the second metal layer LBA and the height H2 of the lower surface of the first metal layer BML may be defined as measured perpendicularly from the upper surface of the second base substrate BSUB2.

As shown in FIG. 5, the second metal layer LBA may be disposed on the same layer as the second barrier layer BA2. The second metal layer LBA and the second barrier layer BA2 may be directly disposed on the upper surface of the second base substrate BSUB2, respectively. The second metal layer LBA may be disposed to be spaced apart from the adjacent second barrier layer BA2. For example, the second metal layer LBA may be disposed to be spaced apart from the side surface of the second barrier layer BA2.

In another embodiment, as shown in FIG. 6, the second metal layer LBA may contact the adjacent second barrier layer BA2. For example, the side surface of the second metal layer LBA and the side surface of the second barrier layer BA2 may be in contact with each other.

The second metal layer LBA may not overlap the first metal layer BML in a plan view. That is, the first metal layer BML and the second metal layer LBA may not overlap each other. The second metal layer LBA may be disposed in an area other than the area in which the first metal layer BML is disposed. In an embodiment, the second metal layer LBA may be disposed in the entire area except for the area in which the first metal layer BML is disposed. The second metal layer LBA may be disposed in a region other than the first metal layer BML to block and absorb the entire light incident from the outside.

As described above, by forming the angle of the side surface of the second barrier layer BA2 to be greater than or equal to 90 degrees, the first metal layer BML and the second metal layer LBA may be formed without using a mask. In addition, by forming the second metal layer LBA in a region other than the region where the first metal layer BML is disposed, it is possible to block the heat of the laser from being transferred to the second base substrate BSUB2 when the active layer of the thin film transistor is crystallized. Accordingly, outgassing and peeling of the second base substrate BSUB2 may be improved.

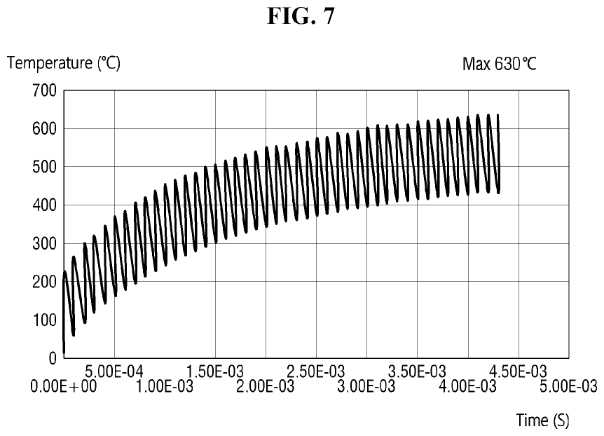

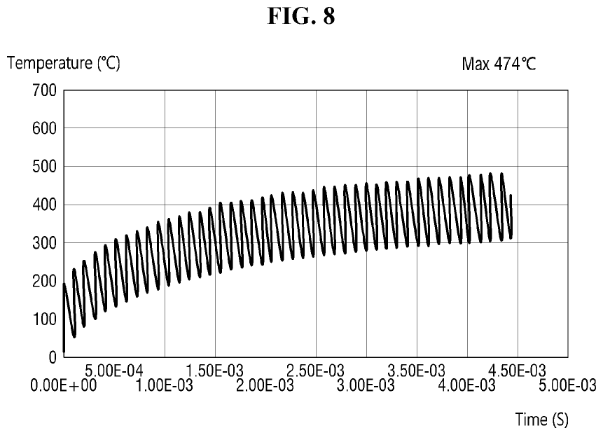

FIG. 7 is a graph illustrating a temperature of a second base substrate during SLA crystallization according to a comparative example. FIG. 8 is a graph illustrating a temperature of a second base substrate during SLA crystallization according to a one embodiment.

Referring to FIG. 7, when the crystallization of the active layer proceeded on the substrate on which only the lower metal layer was disposed without the light blocking layer, the temperature of the second base substrate increased as the laser irradiation time passed, and a maximum of 630 degrees was observed.

On the other hand, referring to FIG. 8, in the case of a substrate having the light blocking layer and the lower metal layer, the maximum temperature of the second base substrate was 474 degrees Celsius.

Through this, by providing the second metal layer LBA of FIG. 4, the transfer of heat by the laser beam irradiated during crystallization of the active layer to the second base substrate BSUB2 is blocked and absorbed. Accordingly, the display device according to one embodiment may improve outgassing and exfoliation of the second base substrate BSUB2 by a laser beam.

Referring to FIG. 4, the first buffer layer BFT may be disposed on the first metal layer BML, the second barrier layer BA2, and the second metal layer LBA. The first buffer layer BFT may serve to alleviate the lower step difference and block the impurities thereunder. The first buffer layer BFT may include silicon nitride, silicon oxide, or silicon nitride oxide, and preferably, silicon nitride. The sum of the thickness of the first buffer layer BFT and the second barrier layer BA2 is equal to or greater than 5000 Å, so that a lower step difference may be reduced.

The second buffer layer BF2 may be disposed on the first buffer layer BFT. The second buffer layer BF2 may have a single-layer structure including silicon nitride, silicon oxide, or silicon nitride oxide. Also, the second buffer layer BF2 may have a stacked structure of a silicon nitride layer and a silicon oxide layer. For example, the second buffer layer BF2 may have a double-layer structure in which a silicon oxide layer is stacked on a silicon nitride layer. However, the present disclosure is not limited thereto.

The driving thin film transistor DTR and the switching thin film transistor STR may be disposed on the second buffer layer BF2. Here, the driving thin film transistor DTR may be the fifth transistor of FIG. 3 described above, and the switching thin film transistor STR may be the second transistor. The driving thin film transistor DTR may include the first active layer ACT1, a first gate electrode G1, a first source electrode S1, and a first drain electrode D1 and the switching thin film transistor STR may include the second active layer ACT2, a second gate electrode G2, a second source electrode S2, and a second drain electrode D2.

Specifically, the first active layer ACT1 and the second active layer ACT2 may be disposed on the second buffer layer BF2. The first active layer ACT1 and the second active layer ACT2 may each be disposed to overlap both the second barrier layer BA2 and the first metal layer BML.

The first active layer ACT1 and the second active layer ACT2 may include polycrystalline silicon. Polycrystalline silicon may be formed by crystallizing amorphous silicon. Examples of the crystallizing techniques may include rapid thermal annealing (“RTA”), solid phase crystallization (“SPC”), excimer laser annealing (“ELA”), solid laser annealing (“SLA”), metal induced crystallization (“MIC”), metal induced lateral crystallization (“MILC”), sequential lateral solidification (“SLS”), etc. In an embodiment, the amorphous silicon of the first active layer ACT1 and the second active layer ACT2 may be crystallized using an SLA method.

The gate insulating layer GI may be disposed on the first active layer ACT1 and the second active layer ACT2. The gate insulating layer GI may serve as a gate insulating layer of each of the thin film transistors DTR and STR. Although it is exemplified that the gate insulating layer G1 is completely disposed on the second buffer layer BF2 in the drawings, the present disclosure is not limited thereto. In some embodiments, the gate insulating layer GI may be partially disposed on the first active layer ACT1 and the second active layer ACT2. The gate insulating layer GI may include silicon oxide, silicon nitride, silicon oxynitride, or the like.

A first conductive layer may be disposed on the gate insulating layer G1. The first conductive layer may include the first gate electrode G1 of the driving thin film transistor DTR and the second gate electrode G2 of the switching thin film transistor STR. The first gate electrode G1 may be disposed to overlap the channel region of the first active layer ACT1 in the third direction DR3, which is the thickness direction of the display device 10, and the second gate electrode G2 may be disposed to overlap the channel region of the second active layer ACT2 in the third direction DR3, which is the thickness direction. Although not shown in the drawings, the first conductive layer may further include one electrode of the storage capacitor.

The first conductive layer may include at least one metal selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first conductive layer may be a single layer or a multilayer.

An interlayer-insulating layer ILD may be disposed on the first conductive layer. The interlayer-insulating layer ILD may function as an insulating layer between the first conductive layer and other layers disposed thereon and may protect the first conductive layer. The interlayer-insulating layer ILD may include silicon oxide, silicon nitride, silicon oxynitride, or the like.

A second conductive layer may be disposed on the interlayer-insulating layer ILD. The second conductive layer may include source electrodes S1 and S2 and drain electrodes D1 and D2 of each of the thin film transistors DTR and STR. Although not shown in the drawings, the second conductive layer may further include another electrode of the storage capacitor.

The first source electrode S1 and the first drain electrode D1 may be in contact with the first active layer ACT1 of the driving thin film transistor DTR through a contact hole penetrating the interlayer-insulating layer ILD and the gate insulating layer GI, respectively. The second source electrode S2 and the second drain electrode D2 may be in contact with the second active layer ACT2 of the switching thin film transistor STR through a contact hole penetrating the interlayer-insulating layer ILD and the gate insulating layer GI, respectively.

A passivation layer PAS may be disposed on the second conductive layer. The passivation layer PAS may function as an insulating layer between the second conductive layer and other layers and may protect the second conductive layer. The passivation layer PAS may include silicon oxide, silicon nitride, silicon oxynitride, or the like.

A via-layer VIA may be disposed on the passivation layer PAS. The via-layer VIA may include an organic insulating material, for example, an organic insulating material such as polyimide (“PI”), and may form a flat top surface while compensating for a step caused by the lower conductive layers. However, in some embodiments, the via-layer VIA may be omitted.

The display device 10 is a display device layer disposed on the via-layer VIA, and may include an organic light emitting diode 180.

Specifically, a first electrode 181 may be disposed on the via-layer VIA. The first electrode 181 may be connected to the first drain electrode D1 of the driving thin film transistor DTR through a contact hole passing through the via-layer VIA. The first electrode 181 may be an anode electrode or a pixel electrode.

A bank layer BNL may be disposed on the first electrode 181. The bank layer BNL may define an opening OP partially exposing the first electrode 181. The bank layer BNL may be formed of an organic insulating material or an inorganic insulating material. For example, the bank layer BNL may include at least one of a photoresist, a polyimide-based resin, an acrylic resin, a silicone compound, and a polyacrylic resin.

An organic light emitting layer 182 may be disposed on the upper surface of the first electrode 181 and in the opening OP of the bank layer BNL. At least one of a hole injection layer and a hole transport layer may be included between the organic light emitting layer 182 and the first electrode 181, and at least one of an electron transport layer or an electron injection layer may be included on the organic light emitting layer 182.

A second electrode 183 may be disposed on the organic light emitting layer 182 and the bank layer BNL. The second electrode 183 may be a common electrode disposed over a plurality of pixels, or a cathode electrode.

The first electrode 181, the organic light emitting layer 182, and the second electrode 183 described above may constitute the organic light emitting diode 180.

An encapsulation layer 190 may be disposed on the organic light emitting diode 180. Specifically, the encapsulation layer 190 may be disposed on the second electrode 183. The encapsulation layer 190 may cover the organic light emitting diode 180. The encapsulation layer 190 may be a stacked layer in which an inorganic layer and an organic layer are alternately stacked. For example, the encapsulation layer 190 may include a first inorganic encapsulation layer 191, an organic encapsulation layer 192, and a second inorganic encapsulation layer 193 that are sequentially stacked.

Hereinafter, a method of manufacturing a display device according to an embodiment will be described with reference to other drawings.

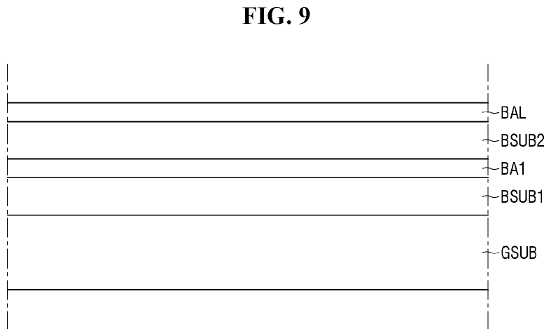

FIGS. 9 to 16 are views for each step illustrating a manufacturing method of a display device according to one embodiment. The following drawings show a manufacturing method of a region corresponding to FIG. 4 described above.

Referring to FIG. 9, the first base substrate BSUB1 is formed on a support substrate GSUB. The support substrate GSUB may include a material having a rigid property to support layers formed thereon. For example, the support substrate GSUB may be a glass substrate. The first base substrate BSUB1 may be formed on the support substrate GSUB using a solution process. The solution process may include, but is not limited to, spin coating, slit coating, inkjet printing, and the like.

Next, the first barrier layer BA1 is formed on the first base substrate BSUB1. The first barrier layer BA1 may be formed by depositing a barrier layer material on the first base substrate BSUB1 over the entire surface. The first barrier layer BA1 may be formed by a method such as low pressure chemical vapor deposition (“LPCVD”), atmospheric pressure chemical vapor deposition (“APCVD”), plasma enhanced chemical vapor deposition (“PECVD”), sputtering, vacuum deposition, or the like.

The second base substrate BSUB2 is formed on the first barrier layer BA1. The second base substrate BSUB2 may be formed in the same manner as the above-described first base substrate BSUB1.

A barrier material layer BAL is deposited on the second base substrate BSUB2 The barrier material layer BAL may be formed by a method such as low pressure chemical vapor deposition (LPCVD), atmospheric pressure chemical vapor deposition (APCVD), plasma enhanced chemical vapor deposition (PECVD), sputtering, vacuum deposition, or the like.

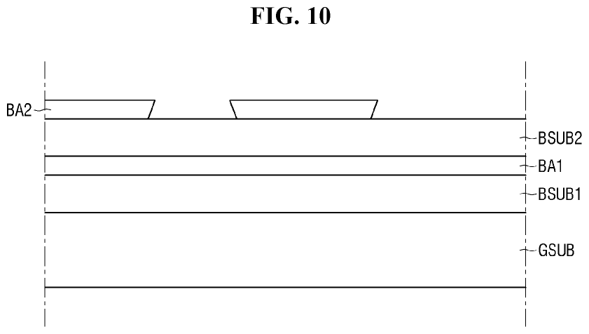

Subsequently, referring to FIG. 10, the second barrier layer BA2 is formed by etching the barrier material layer BAL. Specifically, a photoresist pattern is formed on the barrier material layer BAL and an over-etch is induced by using the photoresist pattern as a mask to form the second barrier layer BA2 having a reverse tapered structure. In the present embodiment, the side surface of the second barrier layer BA2 is illustrated and described as forming an obtuse angle with the upper surface of the second base substrate BSUB2, but the present disclosure is not limited thereto, and may be adjusted in a range of 90 degrees to 150 degrees.

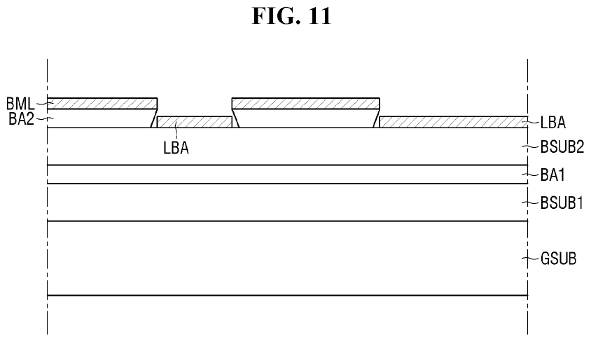

Next, referring to FIG. 11, the first metal layer BML is formed on the second barrier layer BA2 and the second metal layer LBA is formed on the second base substrate BSUB2.

Specifically, a metal material layer is stacked on the second base substrate BSUB2 on which the second barrier layer BA2 is formed. The metal material layer may be formed by sputtering, vacuum deposition, or the like. When a metal material layer is stacked on the second base substrate BSUB2, the first metal layer BML and the second metal layer LBA may be formed by being separated from each other by the second barrier layer BA2. For example, as the second barrier layer BA2 has a reverse tapered structure, the metal material layer may be separated from the side surface of the second barrier layer BA2 so that the first metal layer BML and the second metal layer LBA are formed. That is, the first metal layer BML may be formed on the second barrier layer BA2, and the second metal layer LBA may be formed on the second base substrate BSUB2 between the second barrier layers BA2.

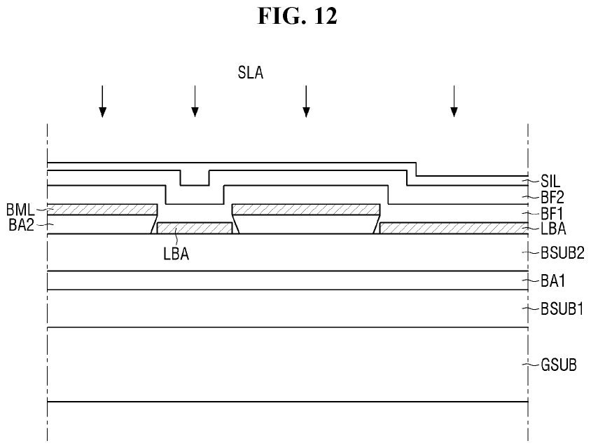

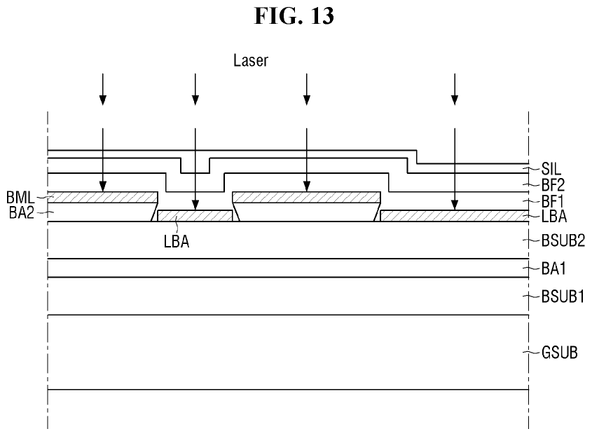

Next, referring to FIGS. 12 and 13, the first buffer layer BF1 and the second buffer layer BF2 are sequentially formed on the second base substrate BSUB2 on which the first metal layer BML and the second metal layer LBA are formed. The first buffer layer BF1 and the second buffer layer BF2 are each formed by a method such as low pressure chemical vapor deposition (LPCVD), atmospheric pressure chemical vapor deposition (APCVD), plasma enhanced chemical vapor deposition (PECVD), sputtering, vacuum deposition, etc.

Next, an amorphous silicon layer SIL is formed on the second buffer layer BF2 The amorphous silicon layer SIL may be formed by a method such as low pressure chemical vapor deposition (LPCVD), atmospheric pressure chemical vapor deposition (APCVD), plasma enhanced chemical vapor deposition (PECVD), sputtering, vacuum deposition, or the like.

Then, a polycrystalline silicon layer is formed by irradiating the amorphous silicon laver SIL to crystalize.

Specifically, the polycrystalline silicon layer may be formed by irradiating a laser beam to the amorphous silicon layer SIL. The laser may intermittently generate a laser beam to irradiate the amorphous silicon layer SIL. For example, the laser may use a solid laser annealing (SLA) method for generating a laser beam having a short wavelength, high power, and high efficiency. The SLA method is a process that can be heat-treated with high laser energy by amplifying and generating high energy using a solid-state laser source.

The laser beam may be irradiated to the amorphous silicon layer SIL while moving in one direction to crystallize the amorphous silicon layer SIL into a polycrystalline silicon layer. The laser may irradiate a laser beam having a pulse energy of about 70) millijoules per square centimeter (mi/cm²) to about 1500 mJ/cm². In one embodiment, the wavelength of the laser beam may be about 308 nanometers (nm), the pulse width may be about 24 nanoseconds (ns), the repetition rate may be about 500 Hertz (Hz), and the average power may be about 500 watts (W), but is not limited thereto.

When the laser beam is irradiated, the laser beam is irradiated to the amorphous silicon layer SIL, but heat may be conducted downward from the amorphous silicon layer SIL as the irradiation time of the laser beam increases. In the present embodiment, as the second metal layer LBA and the first metal layer BML are disposed under the amorphous silicon layer SIL, heat conducted downward may be blocked and absorbed. Accordingly, heat conduction to the second base substrate BSUB2 adjacent to the amorphous silicon layer SIL is blocked, thereby improving outgassing and exfoliation of the second base substrate BSUB2.

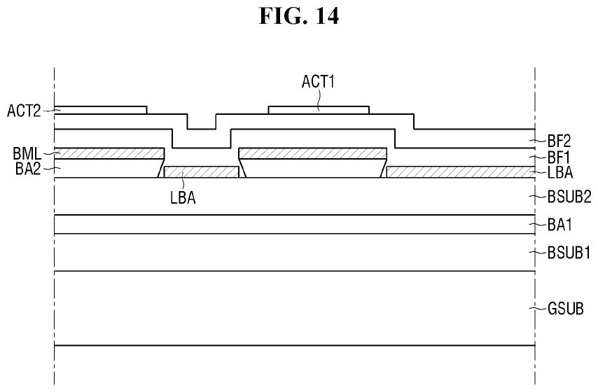

Next, referring to FIG. 14, the polysilicon layer is patterned using a photolithography process to form the first active layer ACT1 and the second active layer ACT2.

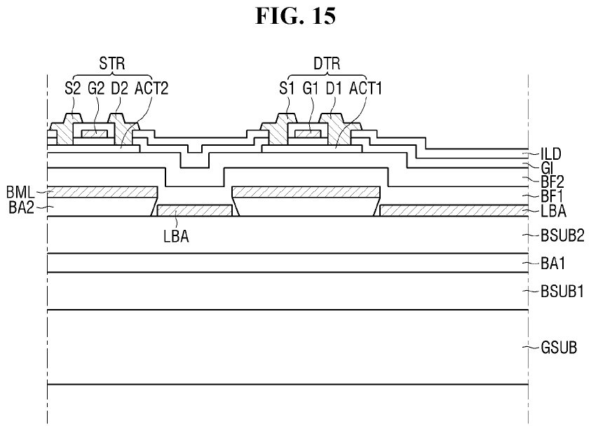

Next, referring to FIG. 15, the gate insulating layer GI is formed on the first active layer ACT1 and the second active layer ACT2, the first conductive layer is stacked on the gate insulating layer GI, and by patterning through a photolithography process, the first gate electrode GI and a second gate electrode G2 are formed. Next, the interlayer-insulating layer ILD is formed on the first gate electrode GI and the second gate electrode G2. Although not shown, contact holes penetrating the interlayer-insulating layer ILD and the gate insulating laver GI to expose the active layers ACT1 and ACT2 are formed.

Then, the second conductive layer is stacked on the interlayer-insulating layer ILD and patterned by a photolithography process to form source electrodes S1 and S2 and drain electrodes D1 and D2. The first source electrode S1 and the first drain electrode D1 are in contact with the first active layer ACT1, and the second source electrode S2 and the second drain electrode D2 are in contact with to the second active layer ACT2. Accordingly, the switching thin film transistor STR and the driving thin film transistor DTR are formed.

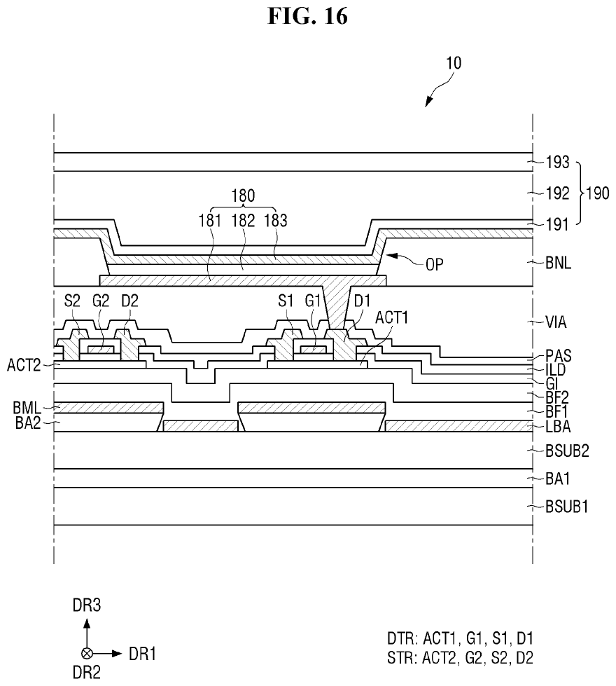

Next, referring to FIG. 16, the passivation layer PAS is formed on the switching thin film transistor STR and the driving thin film transistor DTR, and an organic material is coated on the passivation layer PAS to form a via-layer VIA. A contact hole penetrating the via-layer VIA and the passivation layer PAS to expose the first drain electrode D1 is formed.

Then, a transparent conductive material is stacked on the via-layer VIA and patterned by a photolithography process to form the first electrode 181. The first electrode 181 is connected to the first drain electrode D1 through a contact hole. Then, an organic material is coated on the via-layer VIA to form the bank layer BNL defining the opening OP therein exposing the first electrode 181.

Next, the organic light emitting layer 182 is formed on the first electrode 181 exposed by the opening OP, and a conductive layer is stacked on the organic light emitting layer 182 and the bank layer BNL to form the second electrode 183. Accordingly, the organic light emitting diode 180 including the first electrode 181, the organic light emitting layer 182, and the second electrode 183 is formed.

Then, the first inorganic encapsulation layer 191, the organic encapsulation layer 192, and the second inorganic encapsulation layer 193 are sequentially formed on the organic light emitting diode 180 to form the encapsulation layer 190. Accordingly, the display device 10 according to one embodiment may be manufactured.

As described above, in the display device 10 according to one embodiment, since the angle of the side surface of the second barrier layer BA2 is greater than or equal to 90 degrees, the first metal layer BML and the second metal layer LBA may be formed simultaneously without using a mask.

In addition, by forming the second metal layer LBA in an area other than the area where the first metal layer BML is disposed, heat by the laser beam may be blocked from being transferred to the second base substrate BSUB2 when the active layer of the thin film transistor is crystallized. Accordingly, outgassing and peeling of the second base substrate BSUB2 may be improved.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a base substrate;
a barrier layer disposed on the base substrate;
a first metal layer disposed on the barrier layer;
a second metal layer disposed on the base substrate and spaced apart from the first metal layer;
a buffer layer disposed on the first metal layer and the second metal layer; and
a plurality of thin film transistors disposed on the buffer layer,
wherein an angle between a side surface of the barrier layer and a bottom surface of the barrier layer is equal to or more than 90 degrees and less than or equal to 150 degrees.

2. The display device of claim 1, wherein the barrier layer has a reversed-tapered shape.

3. The display device of claim 2, wherein the angle between the side surface of the barrier layer and the bottom surface of the barrier layer is greater than 90 degrees and less than or equal to 150 degrees.

4. The display device of claim 2, wherein a width of the bottom surface of the barrier layer is smaller than a width of a top surface of the barrier layer.

5. The display device of claim 1, wherein the first metal layer and the second metal layer contain a same material.

6. The display device of claim 1, wherein the first metal layer is in contact with a top surface of the barrier layer and the second metal layer is in contact with a top surface of the base substrate.

7. The display device of claim 1, wherein the second metal layer is spaced apart from the side surface of the barrier layer.

8. The display device of claim 1, wherein a planar area of the first metal layer is the same as a planar area of the barrier layer.

9. The display device of claim 1, wherein each of thicknesses of the first metal layer and a second metal layer is smaller than a thickness of the barrier layer.

10. The display device of claim 1, wherein a height of atop surface of the second metal layer is smaller than a height of a bottom surface of the first metal layer, and the heights are measured in a direction perpendicular to a top surface of the base substrate.

11. The display device of claim 1, wherein the first metal layer and the second metal layer do not overlap each other in a plan view.

12. A display device comprising:
a first base substrate;
a first barrier layer disposed on the first base substrate;
a first metal layer disposed on the first barrier layer;
a second metal layer disposed on the first base substrate and spaced apart from the first metal layer;
a buffer layer disposed on the first metal layer and the second metal layer; and
a plurality of thin film transistors disposed on the buffer layer,
wherein an angle between a side surface of the first barrier layer and a top surface of the first base substrate is about 90 degrees.

13. The display device of claim 12, wherein the second metal layer is in contact with the side surface of the first barrier layer.

14. The display device of claim 12, wherein the side surface of the first barrier layer and a side surface of the first metal layer are aligned and coincide with each other.

15. The display device of claim 12, wherein the plurality of thin film transistors comprises an active layer, a gate electrode, a source electrode, and a drain electrode, and wherein the active layer overlaps the first metal layer in a plan view.

16. The display device of claim 12, further comprising:
a second base substrate disposed under the first base substrate; and
a second barrier layer disposed between the first base substrate and the second base substrate.

17. A method for fabrication of a display device, comprising:
forming a barrier layer on a base substrate, wherein an angle between a side surface of the barrier layer and a bottom surface of the barrier layer is equal to or more than 90 degrees and less than or equal to 150 degrees;
forming a first metal layer and a second metal layer spaced apart from the first metal layer by stacking a metal material layer on the base substrate;
forming a buffer layer on the first metal layer and the second metal layer;
forming an amorphous silicon layer on the buffer layer, and irradiating a laser to the amorphous silicon layer to form a polycrystalline silicon layer; and
forming an active layer by patterning the polycrystalline layer, and forming a gate electrode, a source electrode, and a drain electrode to form a thin film transistor.

18. The method of claim 17, wherein the barrier layer is formed by forming a barrier material layer on the base substrate and inducing over-etching using a photoresist pattern as a mask.

19. The method of claim 17, wherein the first metal layer and the second metal layer are formed by being separated by the barrier layer when stacking the metal material layer.

20. The method of claim 17, wherein the laser is irradiated using a solid laser annealing (SLA) method.
